(19) United States
(12) Patent Application Publication
(10) Pub. No.: US 2022/0132713 A1
(43) Pub. Date: Apr. 28, 2022

(54) COMPONENT FEEDING DEVICE

(71) Applicant: Panasonic Intellectual Property Management Co., Ltd., Osaka (JP)

(72) Inventors: Yoshinori ISOBATA, Fukuoka (JP); Atuyuki HORIE, Fukuoka (JP)

(21) Appl. No.: 17/427,387

(22) PCT Filed: Jan. 21, 2020
(86) PCT No.: PCT/JP2020/001880

§ 371 Date: Jul. 30, 2021

(30) Foreign Application Priority Data
Feb. 8, 2019 (JP) 2019-021110

(51) Int. Cl. H05K 13/04; B65H 23/00; B65H 20/02

(52) U.S. Cl. CPC H05K 13/0419; B65H 2701/1942; B65H 20/02; B65H 23/00

(57) ABSTRACT

The component feeding device includes a body portion, a first sprocket, a second sprocket, a peeler, a pair of rollers, and an openable cover. The first sprocket transports the carrier tape to the downstream component pickup position. The second sprocket transports the carrier tape from the component pickup position to the discharge port. The pair of rollers discharges the cover tape peeled off at the peeler. The first sprocket, the second sprocket, and the pair of rollers are disposed below the openable cover.

### TECHNICAL FIELD

The present disclosure relates to a component feeding device that supplies a component in a storage portion formed in a carrier tape to a component mounting device.

### BACKGROUND ART

As a component feeding device that supplies a component to a component mounting device for mounting a component on a board, a tape feeder is widely used to supply the component in a recessed storage portion formed in a carrier tape to a component pickup position. The carrier tape is supplied in a state where an upper surface of the storage portion storing the component is sealed by a cover tape. In the tape feeder, the cover tape is peeled off before a component pickup position in a tape-feeding process of the carrier tape, so that the storage portion is opened and the component can be picked up. The cover tape peeled off from the cover tape is fed by a cover tape feed mechanism in a direction opposite to a tape feed direction and collected in the cover tape storage unit (see, for example, PTL 1 and 2).

### CITATION LIST

### Patent Literature

PTL 1: Japanese Patent Unexamined Publication No. 2010-157647

PTL 2: Japanese Patent Unexamined Publication No. 2012-74749

### SUMMARY OF THE INVENTION

A component feeding device of the present disclosure is a component feeding device that peels, from a carrier tape, a cover tape covering an upper surface of the carrier tape to open a storage portion of the carrier tape, and supplies a component from the opened storage portion to a component mounting device at a component pickup position, the carrier tape having storage portions and feed holes, the storage portions each being the storage portion storing the component and being arranged at regular interval, the feed hole being used for transporting the carrier tape and arranged at regular intervals.

The component feeding device includes a body portion, a first sprocket, a second sprocket, a peeler, a pair of rollers, and an openable cover.

The body portion has a tape transport path, the tape transport path having an insertion port and a discharge port, the tape transport path guiding the carrier tape from the insertion port to the discharge port.

The first sprocket transports the carrier tape to the component pickup position located downstream of the tape transport path by rotating in engagement with the feed hole.

The second sprocket is disposed downstream of the tape transport path with respect to the component pickup position and transports the carrier tape from the component pickup position to the discharge port by rotating in engagement with the feed hole.

The peeler is disposed upstream of the tape transport path with respect to the component pickup and peels off the cover tape from the carrier tape.

The pair of rollers discharges the cover tape which is peeled off by the peeler.

The cover that is openable has a cover portion covering above the tape transport path.

The first sprocket, the second sprocket, and the pair of rollers are disposed below the cover.

### BRIEF DESCRIPTION OF DRAWINGS

FIG. 1 is a configuration explanatory view illustrating an overall configuration of a component feeding device according to an exemplary embodiment.

FIG. 2 is a partial sectional view of the component feeding device of the exemplary embodiment.

FIG. 3 is a plan view of an openable cover of the component feeding device of the exemplary embodiment.

FIG. 4 is a plan view of the openable cover of the component feeding device of the exemplary embodiment.

FIG. 5A is a sectional view which is taken along line A-A of FIG. 4.

FIG. 5B is a sectional view which is taken along line B-B of FIG. 4.

FIG. 5C is a sectional view which is taken along line C-C of FIG. 4.

FIG. 5D is a sectional view which is taken along line D-D of FIG. 4.

FIG. 5E is a sectional view which is taken along line E-E of FIG. 4.

FIG. 6 is a perspective view of the openable cover of the component feeding device of the exemplary embodiment.

FIG. 7 is a partial sectional view of the component feeding device of the exemplary embodiment.

FIG. 8 is an explanatory view of a driving mechanism of a tape transporter in the component feeding device of the exemplary embodiment.

FIG. 9 is a functional explanatory view of the component feeding device of the exemplary embodiment.

FIG. 10 is a functional explanatory view of the component feeding device of the exemplary embodiment.

FIG. 11 is an explanatory view of a procedure of loading work of a short tape in the component feeding device of the exemplary embodiment.

FIG. 12 is an explanatory view of a procedure of loading work of the short tape in the component feeding device of the exemplary embodiment.

FIG. 13 is an explanatory view of a procedure of loading work of the short tape in the component feeding device of the exemplary embodiment.

FIG. 14 is a block diagram illustrating a configuration of a control system of the component feeding device of the exemplary embodiment.

FIG. 15 is a flowchart of a tape transport process in an automatic loading mode in the component feeding device of the exemplary embodiment.

FIG. 16 is a flowchart of a tape transport process in a splicing mode in the component feeding device of the exemplary embodiment.

FIG. 17 is a flowchart of a tape transport process in a short tape mode in the component feeding device of the exemplary embodiment.

FIG. 18 is an explanatory view of a modified example of an openable cover used in the component feeding device of the exemplary embodiment.

FIG. 19 is an explanatory view of a modified example of the openable cover used in the component feeding device of the exemplary embodiment.

FIG. 20 is a sectional view which is taken along line F-F of FIG. 19.

FIG. 21 is a perspective view of a carrier tape which is a work target in the component feeding device of the exemplary embodiment.

FIG. 22 is an explanatory view of a modified example of a fitting position of connecting portion detection means in the component feeding device of the exemplary embodiment.

FIG. 23 is an explanatory view of a modified example of a fitting position of the connecting portion detection means in the component feeding device of the exemplary embodiment.

### DESCRIPTION OF EMBODIMENTS

A carrier tape is supplied from a supplier in a state of being wound and stored in a supply reel. Installation on a tape feeder is usually performed by a supply reel unit, but at a production site, the carrier tape itself that is not wound on the supply reel may be directly inserted to the tape feeder depending on a situation. For example, there is a case where a production amount of a target product is small and the number of components required is small, there is a case where inventory components which are residual components in a previous production and exist in a scrap tape state are used, and the like. In such a case, it is necessary to install the carrier tape in a form of a so-called short tape having a short length, to the tape feeder.

However, in the related art, there are the following problems related to the handling of the cover tape when the carrier tape in the form of the short tape having a short length is installed. That is, when the carrier tape is installed on the tape feeder, it is necessary to fold back the cover tape peeled off from a tip portion of the carrier tape in a tape feed direction to an opposite side in the tape feed direction, guide the cover tape to a cover tape feed mechanism, and set the cover tape to be fed into a cover tape storage unit.

However, in the related art, the cover tape feed mechanism is provided at a position separated from a peeling-off position where the cover tape is peeled off on the side opposite to the tape feed direction. Therefore, it takes a lot of complicated process and labor to handle the peeled-off cover tape. That is, in order to sandwich the tip portion of the cover tape peeled off at the peeling-off position between tape feed rollers of the cover tape feed mechanism, it is necessary to secure a sufficient length of the cover tape peeled off from the carrier tape. Therefore, in the related art, in order to secure the length of the peeled-off cover tape, it required a process of removing in advance the carrier tape corresponding to a range thereof, adding the cover tape having a required length, or the like. As described above, in the conventional tape feeder, complicated process and labor were required when the tape feeder in the form of the short tape having a short length is directly installed to the tape feeder. Therefore, there has been a demand for a measure capable of easily installing the short tape having a short length.

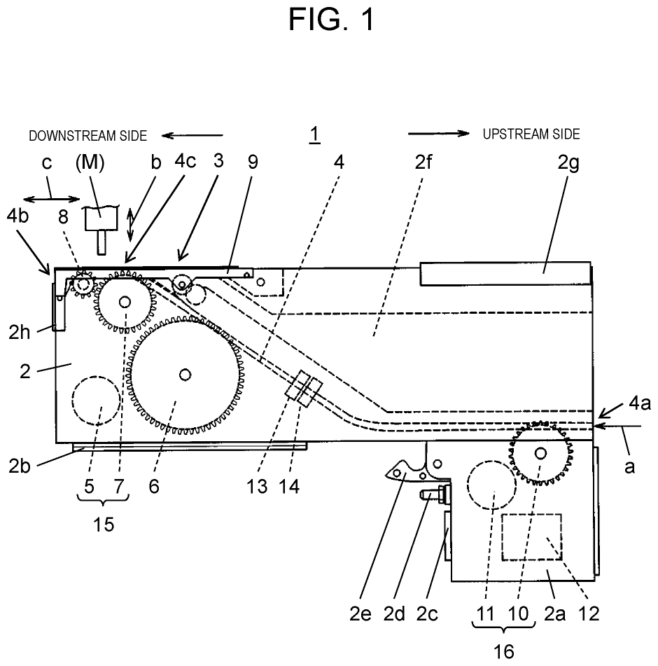

Next, exemplary embodiments of the present disclosure will be described with reference to the drawings. First, with reference to FIG. 1, an overall configuration of tape feeder 1 which is a component feeding device in the present exemplary embodiment will be described. Tape feeder 1 has a function of supplying a component stored in carrier tape 20 for the component supply, to a component mounting device (not illustrated).

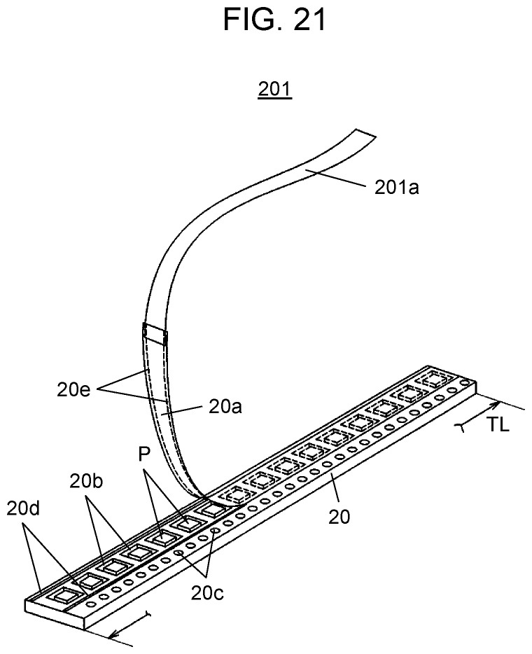

As illustrated in FIG. 21, carrier tape 20 is formed with storage portions 20b for storing components P which are mounting targets and feed holes 20c for transport at regular intervals. The transport of carrier tape 20 is performed by rotating a sprocket provided with an engagement pin that engages with feed hole 20c. An upper surface of carrier tape 20 is covered with cover tape 20a for sealing storage portion 20b.

Cover tape 20a is adhered to carrier tape 20 via an adhesive portion formed by an adhesive on an adhesion interface with carrier tape 20. In a state where cover tape 20a is peeled off from carrier tape 20, in the adhesion interface (surface of carrier tape 20 and rear surface of cover tape 20a) between carrier tape 20 and cover tape 20a, marks 20d and 20e of respective adhesive portions remain and adhere to each other.

When component P is supplied by tape feeder 1, cover tape 20a is peeled off from carrier tape 20 to open storage portion 20b. Component P is picked up from opened storage portion 20b at a component pickup position set in the vicinity of a downstream end portion of tape feeder 1, and is supplied to the component mounting device. In the present exemplary embodiment, carrier tape 20 supplied by tape feeder 1 includes not only hoop-shaped carrier tape 20 which is a normal supply form but also short tape 201 cut by amorphous length dimension TL as illustrated in FIG. 21. Therefore, in the present exemplary embodiment described below, consideration is given such that tape installing work can be performed on such short tape 201 with good workability.

Tape feeder 1 is configured by disposing elements described below on body portion 2 formed of a plate-shaped frame. These elements are covered by side covers (not illustrated) provided on both sides. As illustrated in FIG. 1, body portion 2 is provided with tape transport path 4 that guides carrier tape 20 from insertion port 4a which is open at a lower portion on an upstream side to discharge port 4b set in the vicinity of an end portion of an upper surface on a downstream side.

Carrier tape 20 introduced (arrow a) from insertion port 4a into tape transport path 4 is transported to the upper surface of body portion 2 via an oblique portion provided in a middle of body portion 2 and reaches component pickup position 4c. At component pickup position 4c, a nozzle of component mounting device M (not illustrated) moves up and down (arrow b) to perform a component pickup operation, so that component P is picked up from storage portion 20b. Picked-up component P is transferred (arrow c) to the component mounting device by a mounting head and mounted on a board of a work target. The transport of carrier tape 20 in the above-mentioned component supply is performed by tape transporter 3 described below.

Tape transporter 3 includes first motor 5, transport sprocket 6, positioning sprocket 7, and discharge sprocket 8. By driving transport sprocket 6, positioning sprocket 7, and discharge sprocket 8 by first motor 5 which is a driving source, carrier tape 20 inserted from insertion port 4a is transported into tape feeder 1 and is positioned at component pickup position 4c. Tape transporter 3 is covered with openable cover 9, and engagement of carrier tape 20 with positioning sprocket 7 and discharge sprocket 8 is performed by pressing carrier tape 20 to positioning sprocket 7 and discharge sprocket 8 by openable cover 9.

In a tape transporting process for transporting carrier tape 20 along tape transport path 4 by tape transporter 3, cover tape 20a peeled off from carrier tape 20 is folded back to the upstream side, and is collected in cover tape storage unit 2f provided in body portion 2. Carrier tape 20 after component P is picked up at component pickup position 4c is discharged to the downstream side of tape feeder 1 by discharge sprocket 8 via front cover 2h disposed on an end surface of body portion 2.

That is, positioning sprocket 7 is a first sprocket for transporting carrier tape 20 to downstream component pickup position 4c by rotating in engagement with feed hole 20c of carrier tape 20. Discharge sprocket 8 is a second sprocket positioned downstream of component pickup position 4c for transporting carrier tape 20 by rotating in engagement with feed holes 20c of carrier tape 20 from component pickup position 4c to discharge port 4b. Thus, in the present exemplary embodiment, component pickup position 4c is configured to be disposed between positioning sprocket 7 that is the first sprocket and discharge sprocket 8 that is the second sprocket.

By adopting such a configuration, even when the component is supplied by using short tape 201 illustrated in FIG. 21, all storage portions 20b of carrier tape 20 can be positioned at component pickup position 4c. Thus, storage portion 20b, in which the component pickup is not performed at component pickup position 4c, does not occur and occurrence of component loss can be prevented.

Positioning sprocket 7 and first motor 5 are disposed at the downstream portion of tape transport path 4, and constitute first carrier tape transporter 15 that transports carrier tape 20 to component pickup position 4c. In the present exemplary embodiment, second carrier tape transporter 16 is provided, which transports carrier tape 20 introduced from insertion port 4a, from upstream of tape transport path 4 to first carrier tape transporter 15. That is, in tape transport path 4, second carrier tape transporter 16 having a configuration, in which tape carry-in sprocket 10 is rotationally driven by second motor 11, is disposed in the vicinity of the downstream side of insertion port 4a.

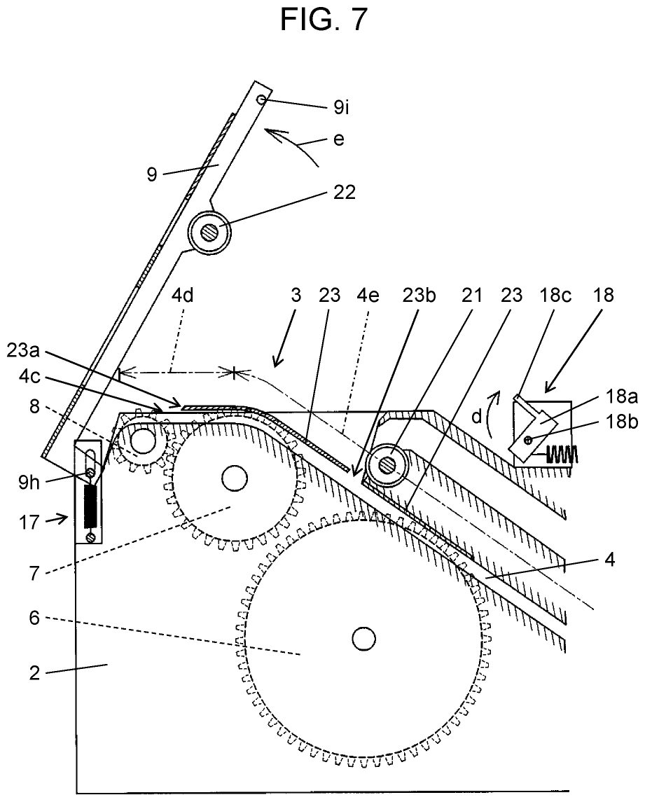

First tape detector 13 and second tape detector 14 using optical sensors are provided at the oblique portion (see climbing section 4e illustrated in FIG. 7) of tape transport path 4 between first carrier tape transporter 15 and second carrier tape transporter 16. First tape detector 13 is carrier tape detection means for detecting carrier tape 20 transported from the upstream side in tape transport path 4. By optically detecting a predetermined portion of carrier tape 20, carrier tape 20 present at the position of first tape detector 13 is detected.

Second tape detector 14 is connecting portion detection means for detecting a connecting portion that connects preceding carrier tape 20 and subsequent carrier tape 20. That is, in a so-called splicing method in which preceding and subsequent two carrier tape 20 of supplied carrier tapes 20 are connected in advance and continuously supplied, a connecting member (splicing tape) connecting two carrier tapes 20 is optically detected so that it is detected that the connecting portion reaches second tape detector 14.

Instead of providing first tape detector 13 and second tape detector 14 together, first tape detector 13 may detect both carrier tape 20 and the connecting portion. In this case, first tape detector 13 is carrier tape detection means that is disposed in tape transport path 4 between first carrier tape transporter 15 and second carrier tape transporter 16, and is capable of detecting carrier tape 20 passing through tape transport path 4, and tape transport path 4.

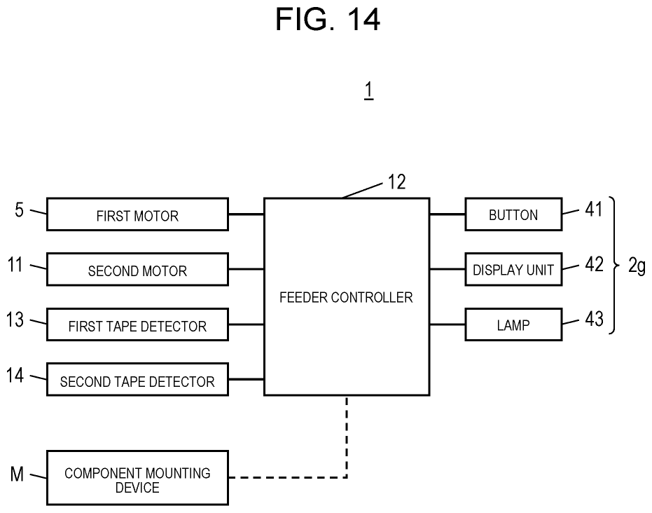

On the lower surface of body portion 2, convex portion 2a for connecting to component mounting device M (see FIG. 14) and fitting rail 2b are provided. By installing fitting rail 2b on a feeder base provided in a component supplier of component mounting device M, tape feeder 1 is set at a predetermined position of the component supplier. Convex portion 2a is provided with connector 2c, air joint 2d, and hook 2e. In a state where tape feeder 1 is set on the feeder base, connector 2c and air joint 2d are fitted to a mating side (component mounting device side) to be in a connected state. At this time, tape feeder 1 is located to be fixed to the feeder base by hook 2e. In this connected state, power supply and air supply from the component mounting device to tape feeder 1, and signal transferring between the component mounting device and tape feeder 1 can be performed.

Feeder controller 12 (controller) that controls an operation of tape feeder 1 is built in convex portion 2a. In a case where tape feeder 1 is connected to component mounting device M, feeder controller 12 is electrically connected to a device controller of component mounting device M via connector 2c. Accordingly, an operation command from the device controller of component mounting device M is transmitted to tape feeder 1, and an operation feedback signal of a component supply operation by tape feeder 1 is transmitted to component mounting device M.

Operation panel 2g, which is located on the upstream side, is provided on the upper surface of body portion 2. Operation panel 2g is provided with button 41, display unit 42, and lamp 43 (see FIG. 14) connected to feeder controller 12. By operating button 41, a predetermined operation input is performed on tape feeder 1. Display unit 42 is a small display panel, a segment type display unit, or the like, and displays an operation state of tape feeder 1. Lamp 43 is a display lamp for notification, and when lamp 43 turns on, notification of an abnormality alarm or the like is performed.

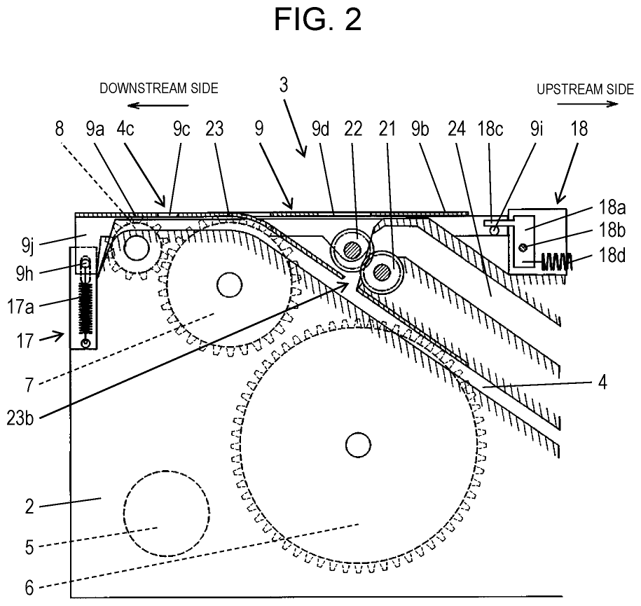

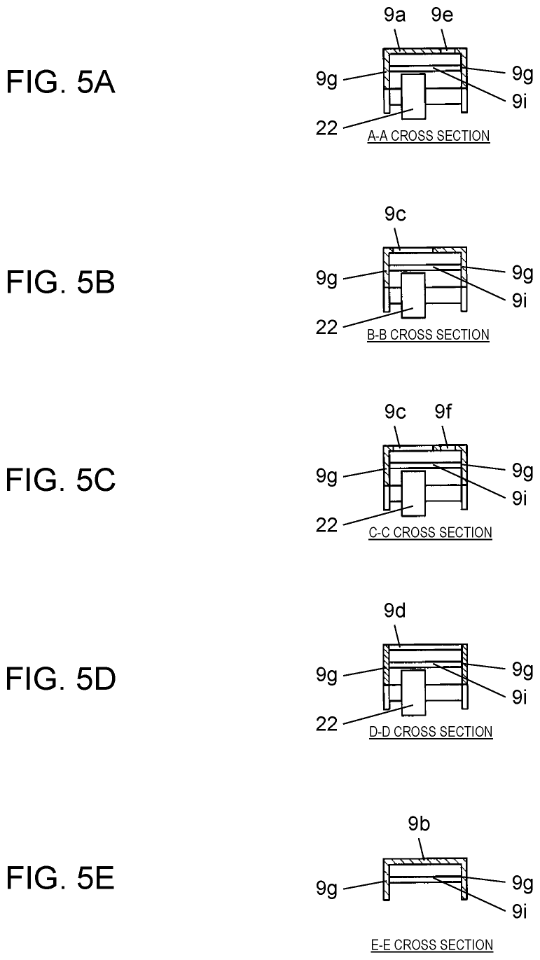

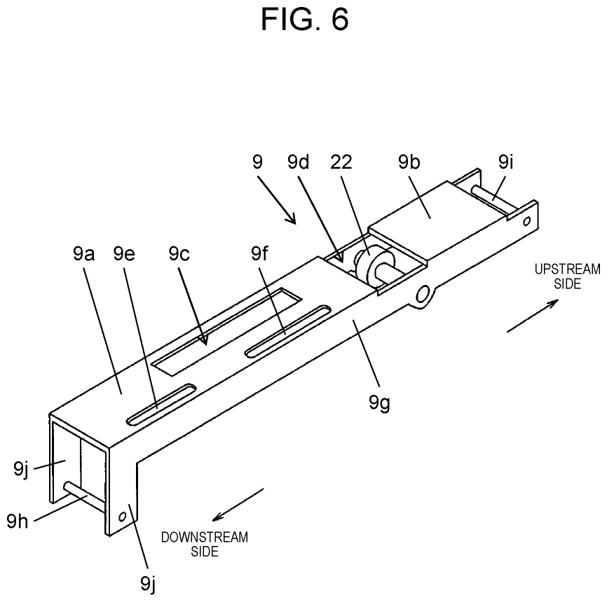

Next, detailed configurations of tape transporter 3 and openable cover 9 will be described with reference to FIGS. 2 to 6. As illustrated in FIG. 2, openable cover 9 is fitted openably and closably to an upper end surface of body portion 2 so as to cover the downstream side of tape transport path 4. As illustrated in FIG. 6, openable cover 9 is an elongated member having a substantially gate-shaped cross section (see FIGS. 5A to 5E) of which a lower surface side is open.

Openable cover 9 is provided with a pair of side surface portions 9g extending downward from both side ends of a top surface forming the gate shape. Locking pin 9i is provided at an end portion on the upstream side of openable cover 9 by connecting the pair of side surface portions 9g. A pair of hanging portions 9j extending downward from side surface portion 9g are provided at an end portion on the downstream side of openable cover 9. Hanging portions 9j are connected by fixing pin 9h.

In FIG. 2, openable cover holder 17 for holding openable cover 9 is provided at the tip portion on the downstream side of body portion 2. In body portion 2, openable cover locking unit 18 for locking the end portion on the upstream side of openable cover 9 is provided on the upstream side of openable cover holder 17. In a state where openable cover 9 is fitted to body portion 2, fixing pin 9h at the end portion on the downstream side of openable cover 9 is pivotally supported by a vertically long elongated hole provided at openable cover holder 17, and is urged downward by urging spring 17a provided in openable cover holder 17.

In a state where openable cover 9 is closed with respect to body portion 2, locking pin 9i provided at the end portion on the upstream side of openable cover 9 is locked by openable cover locking unit 18. Openable cover locking unit 18 includes locking block 18a provided with locking member 18c capable of locking to locking pin 9i and pivotally supported by pivot pin 18b. Urging spring 18d that urges locking member 18c in a pushing down direction is connected to locking block 18a. Therefore, in a state where openable cover 9 is closed, locking pin 9i is pushed down by locking member 18c to be locked.

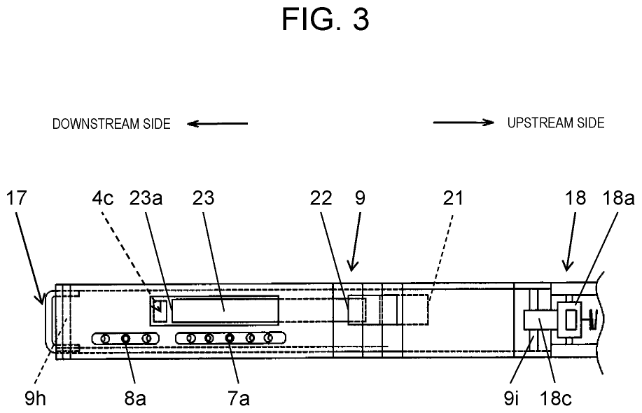

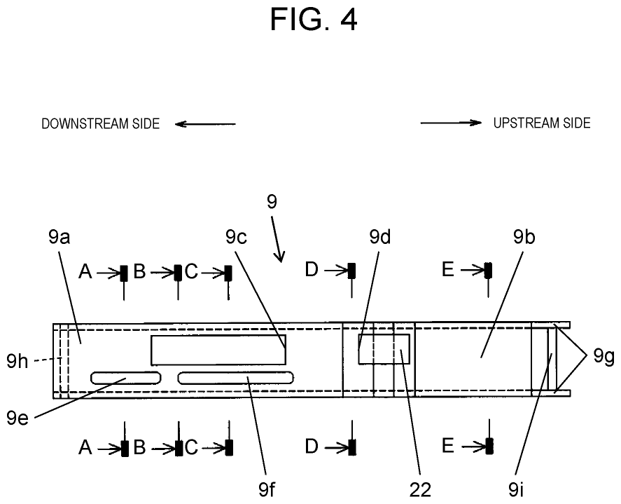

FIG. 3 illustrates the upper surface of openable cover 9 in a state of being fitted to body portion 2 in this way. FIG. 4 illustrates the disposition of the opening portions on the upper surface of openable cover 9. As illustrated in FIG. 4, flat first cover portion 9a and second cover portion 9b are provided on the upper surface of openable cover 9. First cover portion 9a and second cover portion 9b cover above tape transport path 4 in a state where openable cover 9 is fitted to body portion 2. That is, openable cover 9 has a cover portion (first cover portion 9a and second cover portion 9b) that covers above tape transport path 4.

On the upper surface of openable cover 9, first opening portion 9c, second opening portion 9d, first relief portion 9e, and second relief portion 9f are provided as openings. First opening portion 9c is an opening for picking up the component, and an end portion region on a downstream side of first opening portion 9c coincides with component pickup position 4c in tape transport path 4. A downstream portion of tape guide 23 described below is fitted into first opening portion 9c on the upstream side of component pickup position 4c. As described later, in a case where setting of carrier tape 20 is manually performed, the end portion on the downstream side of tape guide 23 has a function of peeler 23a for peeling off cover tape 20a from carrier tape 20 by folding back cover tape 20a at the end portion.

Second opening portion 9d is formed at a position corresponding to driven roller 22 described below. Therefore, in a state where openable cover 9 is closed, driven roller 22 can be accessed from above. In a state where openable cover 9 is lowered with respect to body portion 2 and closed, first relief portion 9e and second relief portion 9f are provided to relief engagement pin 7a of positioning sprocket 7 and engagement pin 8a of discharge sprocket 8 respectively.

FIG. 5A is a sectional view which is taken along line A-A of openable cover 9 of FIG. 4. FIG. 5B is a sectional view which is taken along line B-B of openable cover 9 of FIG. 4. FIG. 5C is a sectional view which is taken along line C-C of openable cover 9 of FIG. 4. FIG. 5D is a sectional view which is taken along line D-D of openable cover 9 of FIG. 4. FIG. 5E is a sectional view which is taken along line E-E of openable cover 9 of FIG. 4. In each of the cross sections illustrated in FIGS. 5A to 5E, the upper surface, side surface portions 9g, and locking pin 9i, which form the gate type cross section of openable cover 9, appear. In FIG. 5A, first cover portion 9a and first relief portion 9e of the upper surface, and driven roller 22 appear. In FIG. 5B, first opening portion 9c provided on the upper surface and driven roller 22 appear. In FIG. 5C, first opening portion 9c and second relief portion 9f provided on the upper surface, and driven roller 22 appear. In FIG. 5D, second opening portion 9d provided on the upper surface and driven roller 22 appear. In FIG. 5E, second cover portion 9b of the upper surface and locking pin 9i appear.

Tape transporter 3 is provided with plate-shaped tape guide 23 disposed along the upper surface of tape transport path 4 so as to cover above transport sprocket 6 and positioning sprocket 7. Tape guide 23 has a function of guiding the upper surface of carrier tape 20 which is transported along tape transport path 4. Tape guide 23 is provided with opening portion 23b for communicating tape transport path 4 upward. Above opening portion 23b, a pair of rollers are disposed, having a configuration in which driving roller 21 and driven roller 22 of cover tape 20a are engaged with each other for peeling-off and discharging.

An air ejection hole (not illustrated) having a function of injecting air at a predetermined timing is open at a position facing opening portion 23b on a bottom surface of tape transport path 4. The tip of cover tape 20a attached to carrier tape 20 is blown up by the air injected from the air ejection hole. Therefore, cover tape 20a can be introduced between driving roller 21 and driven roller 22. In this state, by rotating driving roller 21 and driven roller 22, peeled-off cover tape 20a can be discharged to cover tape storage unit 2f via cover tape discharge path 24 while cover tape 20a is peeled off from carrier tape 20.

Therefore, driving roller 21 and driven roller 22 have a function as a peeler for peeling off cover tape 20a from carrier tape 20 upstream of component pickup position 4c. Driving roller 21 and driven roller 22 have a function of discharging cover tape 20a peeled off by the peeler to cover tape storage unit 2f. That is, in this case, the peeler including driving roller 21 and driven roller 22 has an automatic peeling-off function of peeling off cover tape 20a automatically. This automatic peeling-off function is used in an automatic loading mode in which carrier tape 20 is automatically loaded.

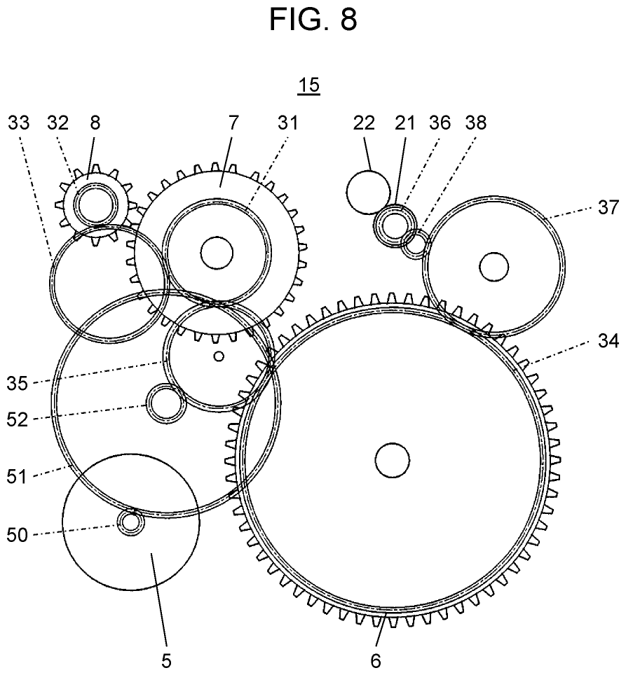

Of the pair of rollers, one driving roller 21 is fixedly disposed in body portion 2, and is rotationally driven by a driving mechanism (see FIG. 8) by using first motor 5 as a driving source. Of the pair of rollers, other driven roller 22 is pivotally supported by side surface portions 9g of openable cover 9, and is rotated by engaging with driving roller 21. That is, in the present exemplary embodiment, openable cover 9 has driven roller 22, whereby driven roller 22 can be attached/detached together with openable cover 9, and when carrier tape 20 is installed to tape feeder 1, cover tape 20a can be easily set.

Positioning sprocket 7 that is the first sprocket, discharge sprocket 8 that is the second sprocket, and driving roller 21 and driven roller 22 that are the pair of rollers are disposed below openable cover 9. With such a configuration, driving roller 21 and driven roller 22 can be disposed at a position close to component pickup position 4c, and has a configuration which is suitable for the case of short tape 201 as a target.

FIG. 7 illustrates a state where openable cover 9 is opened to expose tape transporter 3 and tape transport path 4. That is, first, in openable cover locking unit 18, locking block 18a is pivoted (arrow d) around pivot pin 18b to release the locking of locking pin 9i by locking member 18c. Therefore, in a state where fixing pin 9h on the downstream side is pivotally supported by openable cover holder 17, openable cover 9 can be opened (arrow e). At this time, engagement of driven roller 22 with driving roller 21 is released and driven roller 22 moves together with openable cover 9. In this state, tape transport path 4 and tape guide 23 covering tape transport path 4 are in an exposed state.

As illustrated in FIG. 7, in tape transport path 4, a range downstream of an apex of positioning sprocket 7 is flat section 4d in which tape transport path 4 is flat, and a range upstream of flat section 4d is climbing section 4e from the lower portion to the upper surface of body portion 2. Component pickup position 4c for picking up component P is disposed in flat sections 4d. Driving roller 21 and driven roller 22, which are the pair of rollers, are disposed in a space sandwiched between upstream climbing section 4e and openable cover 9.

Above tape transport path 4 upstream of component pickup position 4c from climbing section 4e, tape guide 23 covering tape transport path 4 is provided separately from openable cover 9 and fixed to body portion 2. Opening portion 23b provided in tape guide 23 is located at a meshing portion between driving roller 21 and driven roller 22. Therefore, cover tape 20a peeled off from carrier tape 20, which is transported through tape transport path 4, can be sandwiched between driving roller 21 and driven roller 22, and be discharged.

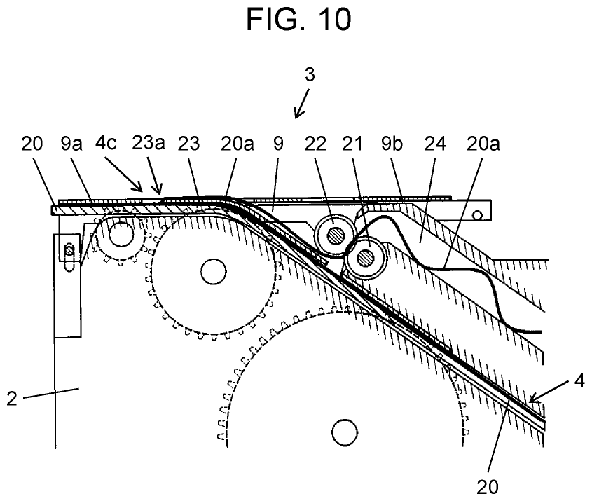

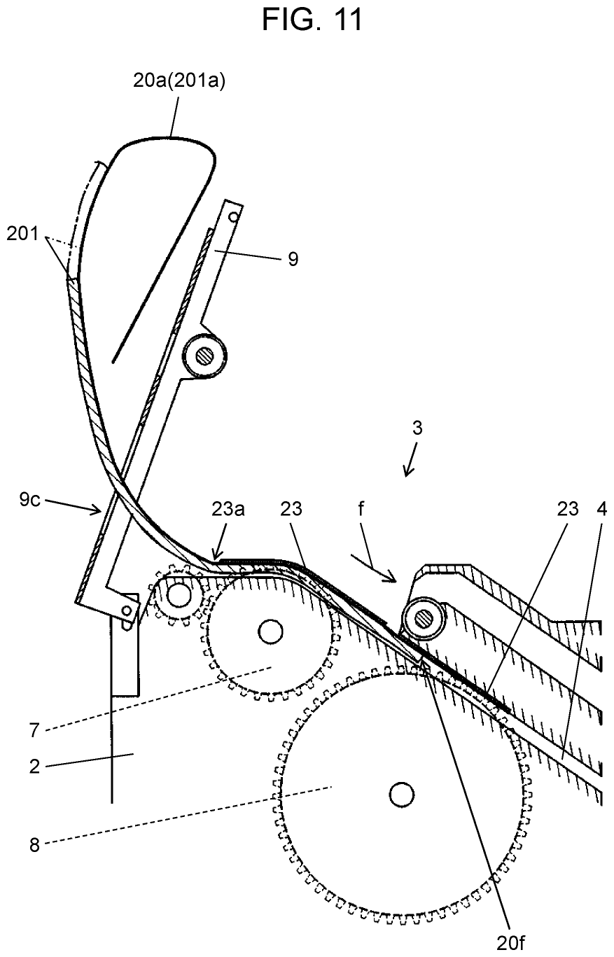

In a case where carrier tape 20 is loaded without using the auto loading function included in tape feeder 1, cover tape 20a is folded back around an edge on the downstream side of tape guide 23 to allow cover tape 20a to be peeled off from carrier tape 20. That is, in this case, the edge on the downstream side of tape guide 23 functions as a peeler for peeling off cover tape 20a from carrier tape 20 upstream of component pickup position 4c (see FIG. 10). The edge on the downstream side of tape guide 23 functions as a guide when short tape 201, which is cut short, is loaded into tape transport path 4 (see FIG. 11).

A configuration of the driving mechanism in first carrier tape transporter 15 will be described with reference to FIG. 8. In FIG. 8, first transmission gear 51 meshes with driving gear 50 coupled to a rotation shaft of first motor 5, and third transmission gear 35 meshes with second transmission gear 52 provided coaxially with first transmission gear 51. Third transmission gear 35 meshes with positioning sprocket gear 31 provided coaxially with positioning sprocket 7, which positions carrier tape 20, and transport sprocket gear 34 (fourth gear) provided coaxially with transport sprocket 6 which transports carrier tape 20 until positioning sprocket 7.

Positioning sprocket gear 31 meshes with fourth transmission gear 33 for transmitting a torque to discharge sprocket gear 32 provided coaxially with discharge sprocket 8 which discharges carrier tape 20. Fifth transmission gear 37 meshes with transport sprocket gear 34. Fifth transmission gear 37 meshes with sixth transmission gear 38 that transmits a torque to peeling-off roller gear 36 provided coaxially with driving roller 21. Therefore, the torque of positioning sprocket gear 31 is transmitted to driving roller 21 and driven roller 22 which are the pair of rollers for tape-feeding cover tape 20a peeled off from carrier tape 20 by fifth transmission gear 37, sixth transmission gear 38, and peeling-off roller gear 36.

In the above configuration, by driving first motor 5 to generate the torque, the torque is transmitted to positioning sprocket gear 31, discharge sprocket gear 32, transport sprocket gear 34, and peeling-off roller gear 36 via a plurality of gears. Therefore, the torque is transmitted to positioning sprocket 7, discharge sprocket 8, transport sprocket 6, and driving roller 21 provided coaxially with positioning sprocket gear 31, discharge sprocket gear 32, transport sprocket gear 34, and peeling-off roller gear 36.

That is, positioning sprocket 7 that is the first sprocket, discharge sprocket 8 that is the second sprocket, transport sprocket 6 that is the third sprocket, and driving roller 21 for discharging cover tape 20a are driven by first motor 5 that is a common driving source. By sharing the driving source in this way, driving roller 21 and driven roller 22 for discharging cover tape 20a can be disposed at a position close to component pickup position 4c, and a configuration which is suitable for the use of short tape 201 can be realized.

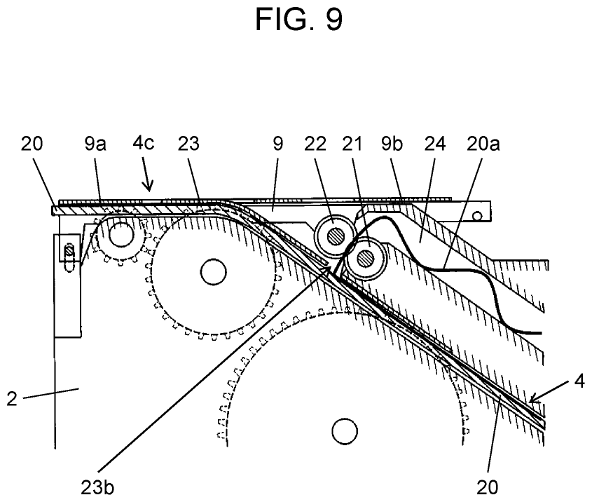

FIG. 9 illustrates a state where carrier tape 20 is set in the automatic loading mode in which carrier tape 20 is automatically loaded. The tip portion of cover tape 20a is introduced between driving roller 21 and driven roller 22 via opening portion 23b by air injection. By rotating these rollers in this state, cover tape 20a is sandwiched and peeled off from carrier tape 20. Peeled-off cover tape 20a is discharged to cover tape storage unit 2f (see FIG. 1) via cover tape discharge path 24.

FIG. 10 illustrates a state where carrier tape 20 is manually set. The present exemplary embodiment is applied to a case where leading carrier tape 20 is set in the splicing mode in which a plurality of carrier tapes 20 connected by splicing are continuously supplied. In this case, in a state where openable cover 9 is opened (see FIG. 7), leading carrier tape 20 is transported along tape transport path 4, and the tip portion reaches the downstream side of peeler 23a of tape guide 23.

Next, in this state, cover tape 20a is manually peeled off from carrier tape 20, and peeler 23a is folded back and guided to cover tape discharge path 24. By closing openable cover 9 in this state, cover tape 20a is in a sandwiched state between driving roller 21 and driven roller 22. Therefore, cover tape 20a can be peeled off from carrier tape 20 by these rollers and discharged to cover tape storage unit 2f.

FIGS. 11, 12, and 13 illustrate loading work of short tape 201, in which carrier tape 20 is cut into short pieces, into tape feeder 1. As illustrated in FIG. 21, short tape 201 that is the work target is a short tape cut into an atypical tape length TL. Prior to the loading work, short tape 201 is pretreated for peeling off cover tape 20a.

Only the base tape portion of the tip portion of short tape 201 is cut off so that the tip portion of cover tape 20a to be peeled off can be guided to the upstream side and sandwiched between driving roller 21 and driven roller 22 (See FIG. 11), or additional dummy tape 201a is added to the tip portion of cover tape 20a (see FIG. 21) to secure a required length for guiding cover tape 20a to the upstream side. In the loading work of short tape 201, as illustrated in FIG. 11, first, rear end portion 20f of short tape 201 passing through first opening portion 9c of openable cover 9 from the upper surface side is inserted into the upstream side from a gap between peeler 23a that is the edge on the downstream side of tape guide 23 and tape transport path 4 (arrow f). That is, in the present exemplary embodiment, the opening portion where peeler 23a is located in tape transport path 4 is a short tape loading port into which short tape 201 is inserted.

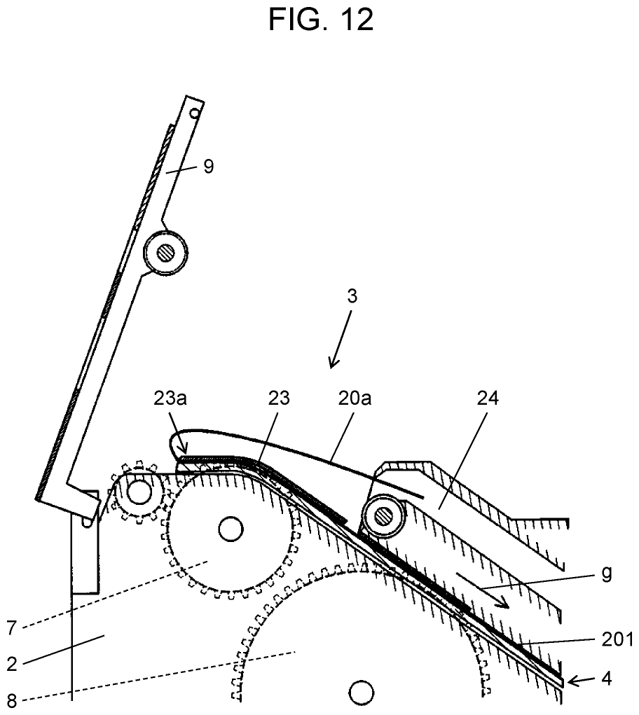

After that, as illustrated in FIG. 12, short tape 201 is inserted further into the upstream side (arrow g), and the tip portion of short tape 201 from which cover tape 20a is peeled off substantially matches with the position of peeler 23a. When short tape 201 is loaded, feed hole 20c engages with positioning sprocket 7, engagement pin 7a of discharge sprocket 8, and engagement pin 8a. Next, the tip portion of folded cover tape 20a is inserted into cover tape discharge path 24.

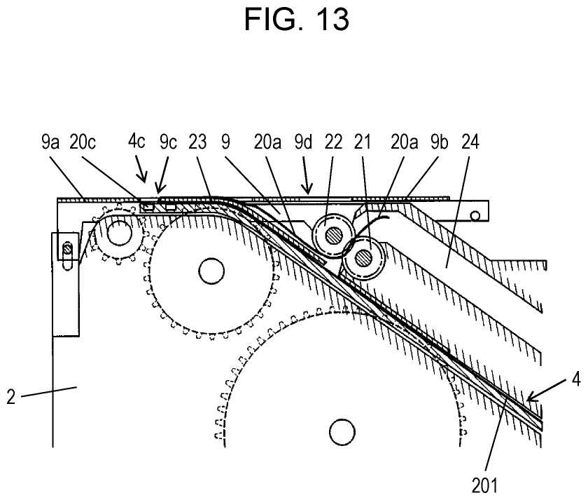

Next, as illustrated in FIG. 13, openable cover 9 is closed and cover tape 20a is pushed down by driven roller 22. Therefore, cover tape 20a is sandwiched between driving roller 21 and driven roller 22, and cover tape 20a can be discharged into cover tape discharge path 24. At this time, the position of short tape 201 is manually adjusted, and heading work is performed so that feed hole 20c at the leading portion matches with component pickup position 4c.

At the same time, slack of cover tape 20a is removed. Since cover tape 20a has poor rigidity and is easily bent, cover tape 20a tends to be in a loosened state on the downstream side of driven roller 22 when openable cover 9 is closed. In such a case, driven roller 22 is manually rotated in a slack removing direction by a finger or a work tool through second opening portion 9d provided in openable cover 9, and the slack state of cover tape 20a is adjusted.

That is, in the present exemplary embodiment, a configuration is provided in which driving roller 21 and driven roller 22 which are the pair of rollers are disposed below openable cover 9, and second opening portion 9d is formed in openable cover 9 for allowing access to at least one of driving roller 21 and driven roller 22. With this configuration, even in a state where the openable cover 9 is closed, driving roller 21 and driven roller 22 disposed below the openable cover 9 can be adjusted to easily remove the slack of cover tape 20a.

A configuration of the control system of tape feeder 1 will be described with reference to FIG. 14. In FIG. 14, in a state where tape feeder 1 is set in component mounting device M, feeder controller 12 is connected to the device controller of component mounting device M. Therefore, feeder controller 12 can send and receive control signals to and from tape feeder 1. Feeder controller 12 is connected to first motor 5 and second motor 11 to control them. Therefore, operations of first carrier tape transporter 15 and second carrier tape transporter 16 are controlled.

Feeder controller 12 is connected to first tape detector 13 and second tape detector 14 to receive detection signals thereof. The operation controls of first carrier tape transporter 15 and second carrier tape transporter 16 are executed based on these detection signals. Feeder controller 12 is connected to button 41, display unit 42, and lamp 43 provided on operation panel 2g.

By operating button 41 to input a predetermined operation to feeder controller 12, an operation command is performed to first carrier tape transporter 15 and second carrier tape transporter 16 in tape feeder 1. Display unit 42 displays an operation state of tape feeder 1 and the like in accordance with a command from feeder controller 12. Lamp 43 lights up in accordance with a command from feeder controller 12 to perform notification of an abnormality alarm or the like.

In the present exemplary embodiment, feeder controller 12 having the above-described configuration controls each portion of tape feeder 1, and thereby three different operation modes described below are realized. First, the first operation mode is an automatic loading mode in which a plurality of carrier tapes 20 are sequentially supplied to tape feeder 1 without splicing. In this automatic loading mode, a detection result of first tape detector 13 is used to control first carrier tape transporter 15 and second carrier tape transporter 16 to allow subsequent carrier tape 20 to follow preceding carrier tape 20 to transport to component pickup position 4c.

In this case, the connecting portion detection function by second tape detector 14 which is the connecting portion detection means is invalid. While first tape detector 13 that is the carrier tape detection means detects carrier tape 20, carrier tape 20 is transported by pitch-feeding by first carrier tape transporter 15 and feed hole 20c of carrier tape 20 is sequentially stopped at component pickup position 4c. When first tape detector 13 does not detect preceding carrier tape 20, following the transport of preceding carrier tape 20 by first carrier tape transporter 15, subsequent second carrier tape 20 is transported by second carrier tape transporter 16.

That is, in the automatic loading mode, in a state where preceding carrier tape 20 and subsequent carrier tape 20 are not connected, subsequent carrier tape 20 following preceding carrier tape 20 is fed to component pickup position 4c and thereby the component stored in the carrier tape 20 can be supplied to component mounting device M.

Next, the second operation mode is a splicing mode in which the preceding and subsequent carrier tapes 20 are connected by splicing and continuously supplied to tape feeder 1. In this splicing mode, carrier tape 20 is transported to component pickup position 4c by the pitch-feeding by first carrier tape transporter 15. In this splicing mode, the connecting portion detection function by second tape detector 14 is valid, and if the connecting portion is detected in the process of transport of carrier tape 20, component mounting device M is notified to that effect.

Second carrier tape transporter 16 may be valid or invalid. In a case where it is valid, only in a case where leading carrier tape 20 is inserted into insertion port 4a, the operation is performed. In the process of the pitch-feeding of carrier tape 20 by first carrier tape transporter 15, when first tape detector 13 does not detect carrier tape 20, the transport is stopped and component mounting device M is notified that the tape runs out.

The third operation mode is a short tape mode in which short tape 201 illustrated in FIG. 21 is the supply target. In the short tape mode, short tape 201 is transported by the pitch-feeding by first carrier tape transporter 15. In this short tape mode, both the carrier tape detection function by first tape detector 13 and the connecting portion detection function by second tape detector 14 are invalid. First carrier tape transporter 15 performs the pitch-feeding of feeds short tape 201 regardless of whether carrier tape 20 is detected by first tape detector 13.

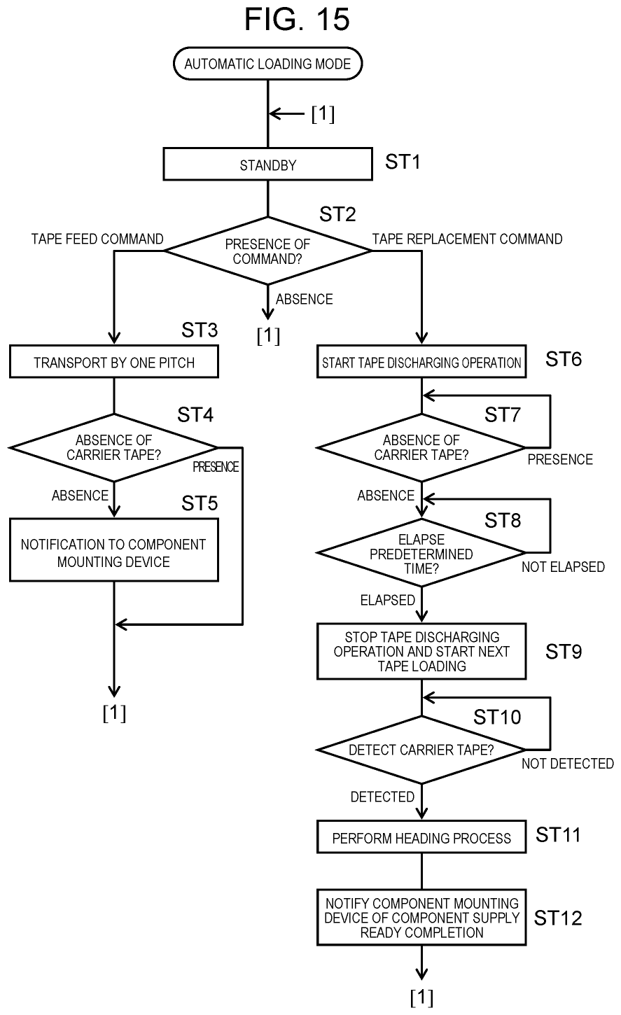

Next, a process flow in the above-described automatic loading mode will be described with reference to FIG. 15. First, tape feeder 1 is in a standby state waiting for an operation command from component mounting device M (ST1), and monitors the presence or absence of the command in this state (ST2). If there is no command, the process returns to (ST1) and the standby is continued. In (ST2), in a case where the tape feed command is received from component mounting device M, first carrier tape transporter 15 is operated to transport carrier tape 20 by one pitch (ST3).

Next, the presence or absence of carrier tape 20 is determined from a detection result of first tape detector 13 (ST4). In a case where there is carrier tape 20, the process returns to (ST1) and waits for the next command. In a case where there is no carrier tape 20, component mounting device M is notified to that effect (ST5). Upon receiving this notification, component mounting device M executes the following process.

First, component mounting device M starts countdown of a tape feeding amount of carrier tape 20 by first carrier tape transporter 15. A counter is set such that a count value becomes zero at a timing when the rear end of carrier tape 20 passes through component pickup position 4c. Before the component runs out, when the rear end of carrier tape 20 passes through component pickup position 4c and the count value becomes zero, a tape replacement command is issued to tape feeder 1. In a case where the component runs out before the count value becomes zero, the same process is performed. The occurrence of component run-out is determined on component mounting device M side. That is, in a case where the pickup of the component by the suction nozzle fails continuously, it is determined that there is no component and the component runs out.

In a case where a tape replacement command is received from component mounting device M in (ST2), the tape discharging operation is started (ST6). That is, at that time, carrier tape 20 that is the transport target of first carrier tape transporter 15 is discharged from discharge port 4b by continuous transport. The presence or absence of carrier tape 20 is monitored by first tape detector 13, it is confirmed that carrier tape 20 is not present, and then it monitors further whether a predetermined time has elapsed (ST8).

Carrier tape 20 is surely discharged from tape transport path 4 by waiting for the elapse of a predetermined time after first tape detector 13 does not detect carrier tape 20. After confirming the elapse of the predetermined time in (ST8), the tape discharging operation by first carrier tape transporter 15 is stopped, and the loading of next carrier tape 20 is started (ST9). That is, next carrier tape 20 is inserted from insertion port 4a, and is tape-fed to the downstream side by continuous transport along tape transport path 4 by second carrier tape transporter 16.

Next, in this tape feeding, it is monitored whether carrier tape 20 is detected (ST10). The tape detection is performed by detecting the tip of next carrier tape 20 by first tape detector 13. If the detection of carrier tape 20 is confirmed in (ST10), a heading process is performed (ST11). That is, the position of carrier tape 20 is adjusted so that feed hole 20c at the head of carrier tape 20 stops at component pickup position 4c.

Thereafter, component mounting device M is notified of component supply ready completion (ST12). In response to this notification, component mounting device M updates data related to the component, and issues a tape feed command to tape feeder 1 at timing instructed by an installation program. The updated data includes the remaining number of components of carrier tape 20, as well as component identification information, lot information, manufacturer information, and the like used as production history information.

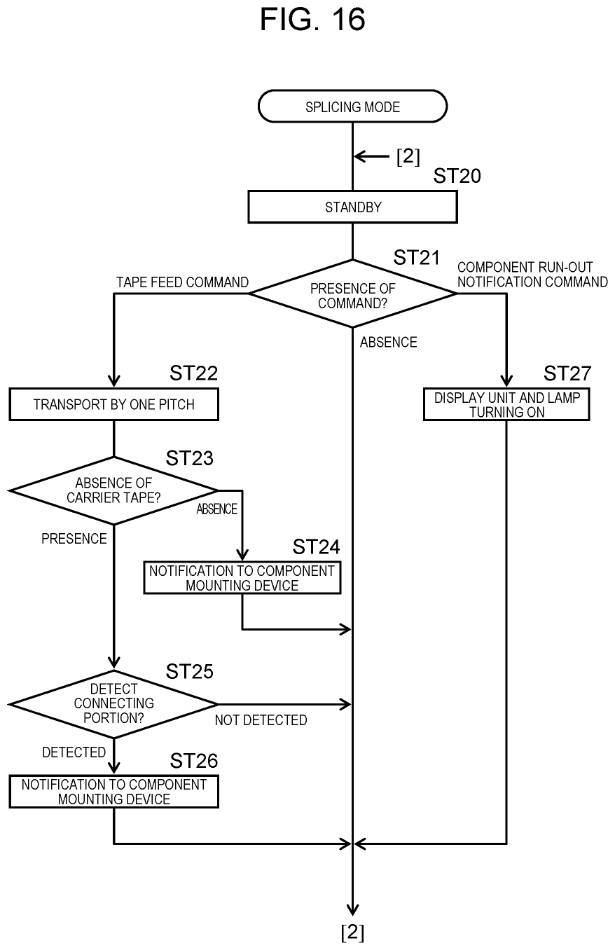

Next, a process flow in the above-described splicing mode will be described with reference to FIG. 16. First, tape feeder 1 is in a standby state waiting for an operation command from component mounting device M (ST20), and monitors the presence or absence of the command in this state (ST21). If there is no command, the process returns to (ST20) and the standby is continued. In (ST21), in a case where the tape feed command is received from component mounting device M, first carrier tape transporter 15 is operated to transport carrier tape 20 by one pitch (ST22).

Next, the presence or absence of carrier tape 20 is determined from the detection result of first tape detector 13 (ST23). In a case where carrier tape 20 is not provided, component mounting device M is notified to that effect (ST24), and then the process returns to (ST20) to wait for the next command. Component mounting device M which has received the notification in (ST24) determines that the component runs out, notifies the operator to that effect by using notification means of component mounting device M, and issues a component run-out notification command to the tape feeder 1. Therefore, in operation panel 2g of tape feeder 1, the component run-out notification is notified by display by display unit 42 or lighting of lamp 43. In a case of the splicing mode, if carrier tape 20 is normally replenished, a situation of the component run-out does not occur, but in a case where splicing is abnormal due to human error, the component run-out may occur.

In a case where it is determined in (ST23) that carrier tape 20 is present, the presence or absence of detection of the connecting portion is determined by second tape detector 14 (ST25). If the connecting portion is not detected, the process returns to (ST20) to continue the standby, and in a case where the connecting portion is detected, component mounting device M is notified to that effect.

Upon receiving this notification, component mounting device M executes the following process. First, component mounting device M starts countdown the tape feeding amount of carrier tape 20 by first carrier tape transporter 15. The counter is set such that the count value becomes zero at the timing when the detected connecting portion passes through component pickup position 4c. When the connecting portion passes through component pickup position 4c and the count value becomes zero, it is determined that carrier tape 20 has been switched, and the data related to the component is updated. In a case where there is the component run-out notification command in (ST21), display unit 42 displays or lamp 43 is turned on (ST27) to notify the operator that the component runs out, and then the process returns to (ST20).

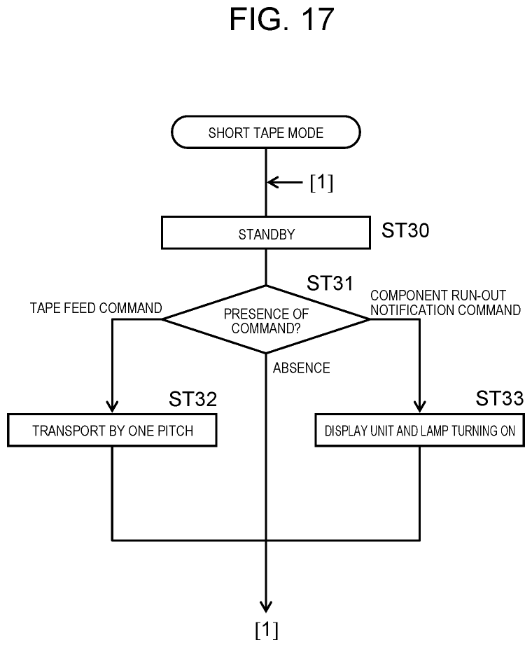

Next, a process flow in the short tape mode described above will be described with reference to FIG. 17. First, tape feeder 1 is in a standby state waiting for an operation command from component mounting device M (ST30), and monitors the presence or absence of the command in this state (ST31). If there is no command, the process returns to (ST30) and the standby is continued. In a case where the tape feed command is received from component mounting device M in (ST31), first carrier tape transporter 15 is operated to transport carrier tape 20 by one pitch (ST32), and then the process returns to (ST30) and the standby is continued. In a case where there is the component run-out notification command in (ST31), the display by display unit 42 or turning-on of lamp 43 is performed (ST33) to notify the operator that the component runs out, and then the process returns to (ST30) and waits.

In tape feeder 1 illustrated in the present exemplary embodiment, any of the above-mentioned first operation mode, second operation mode, and third operation mode can be selectively executed. That is, in the case of the automatic loading mode (first operation mode) in which preceding carrier tape 20 and subsequent carrier tape 20 are fed to component pickup position 4c without being connected, feeder controller 12 uses the detection result of first tape detector 13 that is the carrier tape detection means to control first carrier tape transporter 15 and second carrier tape transporter 16.

In the case of the splicing mode (second operation mode) in which preceding carrier tape 20 and subsequent carrier tape 20 are connected and fed, feeder controller 12 controls first carrier tape transporter 15. When second tape detector 14 which is the connecting portion detection means detects the connecting portion between preceding carrier tape 20 and subsequent carrier tape 20, feeder controller 12 notifies component mounting device M to that effect.

Although the above-described exemplary embodiment illustrates an example in which second tape detector 14, which is the connecting portion detection means, is provided, the connecting portion may be detected by first tape detector 13. That is, in this case, first tape detector 13, which is the carrier tape detection means, can detect carrier tape 20 passing through tape transport path 4 and the connecting portion between preceding carrier tape 20 and subsequent carrier tape 20. When first tape detector 13 detects the connecting portion between preceding carrier tape 20 and subsequent carrier tape 20, component mounting device M is notified to that effect.

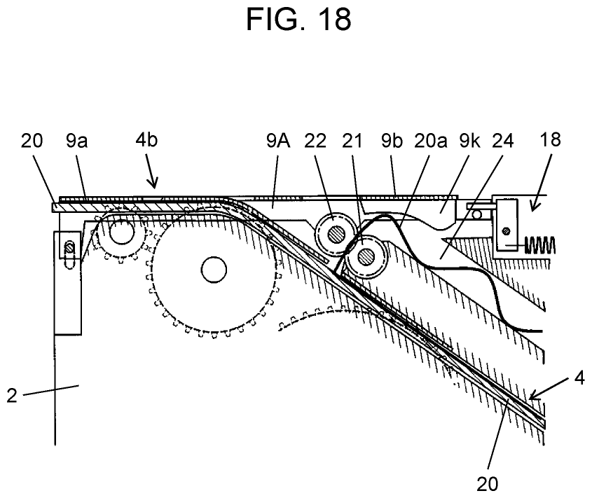

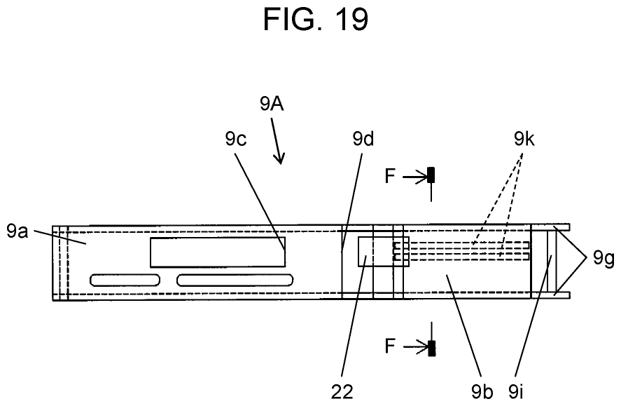

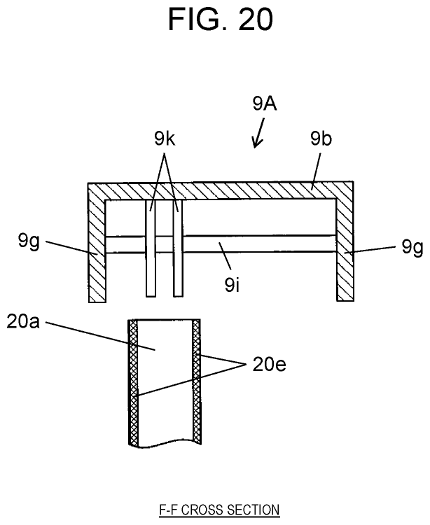

Next, openable cover 9A of a modified example will be described with reference to FIGS. 18 to 20. FIG. 20 illustrates F-F cross section in FIG. 19. As illustrated in FIG. 18, openable cover 9A has a configuration in which fins 9k are disposed on a lower surface side of second cover portion 9b in openable covers 9 illustrated in FIGS. 1 to 13. Fin 9k is a cover tape guide, and provided in a shape that guides cover tape 20a, which is peeled off from carrier tape 20 by driving roller 21 and driven roller 22, which are the pair of rollers, and fed out in a discharge direction to cover tape discharge path 24. By providing such fins 9k, cover tape 20a peeled off from carrier tape 20 and fed out can be smoothly discharged.

As illustrated in FIG. 19, two fins 9k are disposed in parallel on the lower surface of second cover portion 9b at a position corresponding to the position of driven roller 22 in a plan view. As illustrated in FIG. 20, two fins 9k extending downward from a lower surface of second cover portion 9b are disposed at positions avoiding marks 20e of the adhesive portion remaining attached to a rear surface of cover tape 20a in a state of being peeled off from carrier tape 20. By disposing fins 9k in this way, it is possible to prevent marks 20e of the adhesive portion remaining on peeled-off cover tape 20a from adhering to fins 9k. Therefore, cover tape 20a can be smoothly discharged to cover tape discharge path 24 while being stably guided.

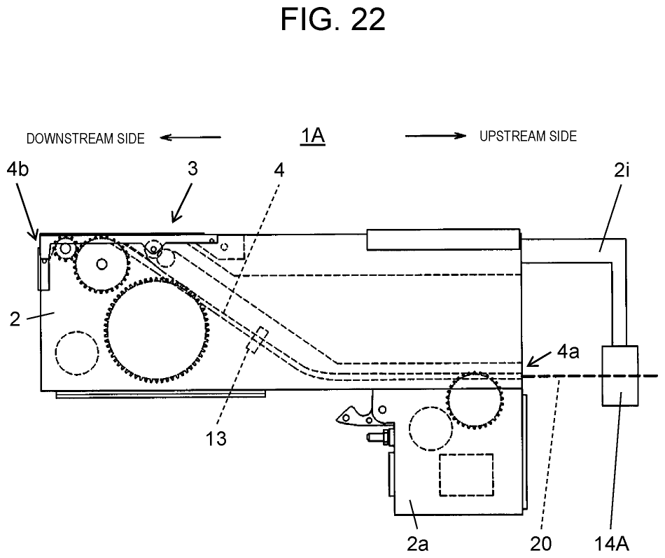

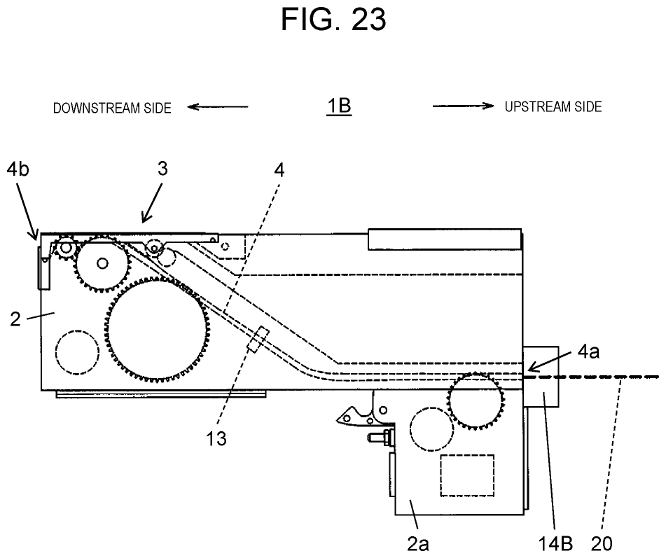

In tape feeder 1 of which the overall configuration is illustrated in FIG. 1, an example is illustrated in which second tape detector 14 which is the connecting portion detection means is disposed in tape transport path 4 that guides carrier tape 20 from insertion port 4a to discharge port 4b in body portion 2. In the present exemplary embodiment, the present disclosure is not limited to such an example, and for example, configurations illustrated in FIGS. 22 and 23 may be adopted.

Similar to tape feeder 1, in tape feeder 1A illustrated in FIG. 22, a configuration is illustrated, which includes body portion 2 provided with tape transport path 4 for guiding carrier tape 20 from insertion port 4a to discharge port 4b. In tape feeder 1A illustrated in FIG. 22, similar to second tape detector 14, a configuration example is illustrated, in which second tape detector 14A which has a function of detecting the connecting portion is disposed on a movement path of carrier tape 20 before carrier tape 20 is introduced into tape transport path 4. That is, in this configuration example, second tape detector 14A, which is disposed at a position separated from insertion port 4a in the movement path of carrier tape 20, is held in holding member 2i extending from body portion 2 to the upstream side.

In tape feeder 1B illustrated in FIG. 23, similarly to tape feeder 1, a configuration is illustrated, which includes body portion 2 provided with tape transport path 4 for guiding carrier tape 20 from insertion port 4a to discharge port 4b. In tape feeder 1B illustrated in FIG. 23, similar to second tape detector 14, a configuration example is illustrated, in which second tape detector 14B having a function of detecting the connecting portion is disposed in insertion port 4a for inserting carrier tape 20 into tape transport path 4. That is, in this configuration example, second tape detector 14B is disposed at a position matching with insertion port 4a on an end surface on the upstream side of body portion 2.

As described above, tape feeder 1 illustrated in the present exemplary embodiment is a component feeding device in which cover tape 20a covering the upper surface of carrier tape 20 is peeled off from carrier tape 20 formed of storage portions 20b for storing component P and feed holes 20c for transport at regular intervals to open storage portion 20b, and component P is supplied from opened storage portion 20b to component mounting device M at component pickup position 4c. Tape feeder 1 includes body portion 2, positioning sprocket 7 as the first sprocket, discharge sprocket 8 as the second sprocket, a peeler, driving roller 21 and driven roller 22 that are the pair of rollers, and openable cover 9.

Body portion 2 has tape transport path 4 that guides carrier tape 20 from insertion port 4a to discharge port 4b.

Positioning sprocket 7 is engaged with feed hole 20c and rotates to transport carrier tape 20 to downstream component pickup position 4c.

Discharge sprocket 8 is disposed downstream of component pickup position 4c, transporting carrier tape 20 from component pickup position 4c to discharge port 4b by rotating in engagement with feed holes 20c.

The peeler peels off cover tape 20a from carrier tape 20 upstream of component pickup position 4c.

Driving roller 21 and driven roller 22, which are the pair of rollers, discharge cover tape 20a which is peeled off at the peeler.

Openable cover 9 has a cover portion covering above tape transport path 4.

Positioning sprocket 7, discharge sprocket 8, driving roller 21, and driven roller 22 are disposed below openable cover 9. With this configuration, driving roller 21 and driven roller 22 having a function of peeling off cover tape 20a can be provided at a position close to component pickup position 4c. Therefore, short tape 201 having cover tape 20a can be easily supported, and short tape 201 can be easily installed.

Tape feeder 1 illustrated in the present exemplary embodiment is a component feeding device, and includes body portion 2, first carrier tape transporter 15, peeler, driving roller 21 and driven roller 22 which are the pair of rollers, and openable cover 9.

Body portion 2 has tape transport path 4 that guides carrier tape 20 from insertion port 4a to discharge port 4b.

First carrier tape transporter 15 has positioning sprocket 7 that transports carrier tape 20 to component pickup position 4c by rotating in engagement with feed hole 20c.

The peeler peels off cover tape 20a from carrier tape 20 upstream of component pickup position 4c.

Driving roller 21 and driven roller 22, which are the pair of rollers, discharge cover tape 20a which is peeled off at the peeler.

Openable cover 9 has a cover portion covering above tape transport path 4.

Driving roller 21 and driven roller 22 are disposed below openable cover 9. Openable cover 9 is formed with second opening portion 9d that allows access to at least one of driving roller 21 and driven roller 22.

With this configuration, when cover tape 20a peeled off from carrier tape 20 is guided to driving roller 21 and driven roller 22 and set, even in a case where large slack occurs in cover tape 20a, driving roller 21 and driven roller 22 can be easily accessed from second opening portion 9d to correct the slack. Therefore, it is possible to prevent the cover tape which is peeled off from the carrier tape from being deformed due to slack, and to perform normal peeling-off of the cover tape.

In this specification, tape feeder 1 capable of selectively executing any one of the first operation mode, the second operation mode, and the third operation mode is described as an example. However, the present invention can also be applied to a dedicated tape feeder that operates only in one of the operation modes, that is, automatic loading feeder having automatic peeling-off function that automatically peels off cover tape 20a, or a normal tape feeder having no automatic peeling-off function.

According to the present disclosure, a short tape having a short length can be easily installed.

### INDUSTRIAL APPLICABILITY

The component feeding device of the present disclosure has an effect that a short tape having a short length can be easily installed, and is useful in a technical field of supplying a component to a component mounting device by a carrier tape storing the component.

### REFERENCE MARKS IN THE DRAWINGS

1, 1A, 1B tape feeder
2 body portion
2a convex portion
2b fitting rail
2c connector
2d air joint
2e hook
2f cover tape storage unit
2h front cover
2i holding member
3 tape transporter
4 tape transport path
4a insertion port
4b discharge port
4c component pickup position
4d flat section
4e climbing section
5 first motor (driving source)
6 transport sprocket
7 positioning sprocket (first sprocket)
7a engagement pin
8 discharge sprocket (second sprocket)
8a engagement pin
9, 9A openable cover
9a cover portion
9b cover portion
9c opening portion
9d opening portion
9e first relief portion
9f second relief portion
9h fixing pin
9i locking pin
9j hanging portion
9k fin
10 tape carry-in sprocket
11 second motor
12 feeder controller
13 tape detector
14 tape detector
14A tape detector
14B tape detector
15 first carrier tape transporter
16 second carrier tape transporter
17 openable cover holder
17a urging spring
18 openable cover locking unit
18a locking block
18b pivot pin
18c locking member
18d urging spring
20 carrier tape
20a cover tape
20b storage portion
20d, 20e mark of adhesive portion
20f rear end portion
21 driving roller
22 driven roller
23 tape guide
23a peeler
23b opening portion
24 cover tape discharge path
31 sprocket gear
32 discharge sprocket gear
33 fourth transmission gear
34 transport sprocket gear
35 third transmission gear
36 peeling-off roller gear
37 fifth transmission gear
38 sixth transmission gear
41 button
42 display unit
43 lamp
50 driving gear
51 first transmission gear
52 second transmission gear
201 short tape
201a dummy tape

1. A component feeding device that peels, from a carrier tape, a cover tape covering an upper surface of the carrier tape to open a storage portion of the carrier tape, and supplies a component from the opened storage portion to a component mounting device at a component pickup position, the carrier tape having storage portions and feed holes, the storage portions each being the storage portion storing the component and being arranged at regular interval, the feed hole being used for transporting the carrier tape and arranged at regular intervals, the component feeding device comprising:
a body portion including a tape transport path, the tape transport path having an insertion port and a discharge port, the tape transport path guiding the carrier tape from the insertion port to the discharge port;
a first sprocket that transports the carrier tape to the component pickup position located downstream of the tape transport path by rotating in engagement with the feed hole;
a second sprocket that is disposed downstream of the tape transport path with respect to the component pickup position and transports the carrier tape from the component pickup position to the discharge port by rotating in engagement with the feed hole;
a peeler that is disposed upstream of the tape transport path with respect to the component pickup and peels off the cover tape from the carrier tape;
a pair of rollers that discharge the cover tape which is peeled off by the peeler; and
a cover that is openable and has a cover portion covering above the tape transport path,
wherein the first sprocket, the second sprocket, and the pair of rollers are disposed below the cover.

2. The component feeding device of claim 1,
wherein one of the pair of rollers is a driving roller driven by a driving source, and
wherein the first sprocket, the second sprocket, and the driving roller are driven by a common driving source.

3. The component feeding device of claim 2,
wherein the other of the pair of rollers is a driven roller rotated by the driving roller, and
wherein the cover has the driven roller.

4. The component feeding device of claim 1,
wherein the component pickup position is disposed in a flat section of the tape transport path, and
wherein the pair of rollers are disposed in a space sandwiched between a climbing section of the tape transport path and the cover, the climbing section being upstream of the tape transport path with respect to the flat section.

5. The component feeding device of claim 4, further comprising:
a tape guide that is separate from the cover and covers above a part of the tape transport path, the part being between the climbing section and the component pickup position,
wherein an edge of the tape guide serves as the peeler, the edge being located downstream of the tape transport path with respect to any other edges of the tape guide.

6. The component feeding device of claim 1,
wherein the peeler is fixed to the body portion, and
wherein the peeler functions as a guide when the tape carrier which is cut short is loaded into the tape transport path.
